(19) United States
(12) Patent Application Publication
(10) Pub. No.: US 2023/0245865 A1
(43) Pub. Date: Aug. 3, 2023

(54) MOVABLE DISK WITH APERTURE FOR ETCH CONTROL

(71) Applicant: LAM RESEARCH CORPORATION, Fremont, CA (US)

(72) Inventors: Chih-Min LIN, San Jose, CA (US); Shuogang HUANG, San Jose, CA (US); Seokmin YUN, Dublin, CA (US); Chih-Yang CHANG, Cupertine, CA (US); Chih-Ming CHANG, Hsin-Chu (TW); Shih-Yuan CHENG, Zhubei-City (TW)

(21) Appl. No.: 18/013,429

(22) PCT Filed: May 17, 2022
(86) PCT No.: PCT/US2022/029539

§ 371 Date: Dec. 28, 2022

Related U.S. Application Data
(60) Provisional application No. 63/191,036, filed on May 20, 2021.

(51) Int. Cl. H01J 37/32

(52) U.S. Cl. CPC H01J 37/32633; H01J 37/321; H01J 2237/3343

(57) ABSTRACT

A processing chamber includes a grid and a first disk. The grid includes a plurality of holes arranged in the processing chamber. The grid partitions the processing chamber into a first chamber in which plasma is generated and a second chamber in which a pedestal is configured to support a substrate. The first disk is arranged in the second chamber. The first disk is movable between the grid and the substrate when supported on the pedestal.

### CROSS-REFERENCE TO RELATED APPLICATIONS

This application claims the benefit of U.S. Provisional Application No. 63/191,036, filed on May 20, 2021. The entire disclosure of the application referenced above is incorporated herein by reference.

### FIELD

The present disclosure relates generally to substrate processing systems and more particularly to a movable disk with aperture for etch control in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing tool typically includes a plurality of stations in which to perform deposition, etching, and other treatments on substrates such as semiconductor wafers. Examples of processes that may be performed on a substrate include, but are not limited to, a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support such as a pedestal in a station. During deposition, gas mixtures including one or more precursors are introduced into the station, and plasma may be optionally struck to activate chemical reactions. During etching, gas mixtures including etch gases are introduced into the station, and plasma may be optionally struck to activate chemical reactions. A computer-controlled robot typically transfers substrates from one station to another in a sequence in which the substrates are to be processed.

### SUMMARY

A processing chamber comprises a grid and a first disk. The grid includes a plurality of holes arranged in the processing chamber. The grid partitions the processing chamber into a first chamber in which plasma is generated and a second chamber in which a pedestal is configured to support a substrate. The first disk is arranged in the second chamber. The first disk is movable between the grid and the substrate when supported on the pedestal.

In another feature, the first disk is movable parallel to the grid.

In another feature, the first disk blocks ions from the plasma from reaching the substrate.

In another feature, the first disk includes at least one or more apertures.

In another feature, the first disk includes an adjustable aperture.

In another feature, the first disk includes an adjustable aperture and a second aperture of a fixed size.

In another feature, the first disk is made of a material selected from a group consisting of diamond-like carbon (C), tantalum (Ta), molybdenum (Mo), aluminum (Al), alumina (Al₂O₃), chromium (Cr), Beryllium (Be), tantalum carbide (TaC), and lead zirconate titanate (PZT) ceramic.

In another feature, the first disk has a smaller diameter than the substrate.

In another feature, the processing chamber further comprises a second disk arranged in the second chamber. The second disk is movable parallel to the grid between the grid and the substrate.

In another feature, the first disk and the second disk are coplanar.

In another feature, the first disk and the second disk have the same geometry.

In another feature, the first disk and the second disk have different geometries.

In another feature, at least one of the first disk and the second disk includes one or more apertures.

In another feature, at least one of the first disk and the second disk includes an adjustable aperture.

In another feature, at least one of the first disk and the second disk includes an adjustable aperture, and at least one of the first disk and the second disk includes a second aperture of a fixed size.

In another feature, a system comprises the processing chamber, an actuator to move the first disk, and a controller to control the actuator.

In another feature, a system comprises the processing chamber, a voltage source to supply a voltage to the grid, an actuator to move the first disk, and a controller to control the voltage supplied to the grid and to control the actuator.

In another feature, a system comprises the processing chamber, where the first disk includes an adjustable aperture; an actuator to move the first disk and to adjust the adjustable aperture; and a controller to control the actuator.

In another feature, a system comprises the processing chamber; first and second actuators to move the first disk and the second disk, respectively; and a controller to control the first and second actuators.

In another feature, a system comprises the processing chamber, where at least one of the first disk and the second disk includes an adjustable aperture; first and second actuators to move the first disk and the second disk, respectively, and to adjust the adjustable aperture; and a controller to control the first and second actuators.

In another feature, a system comprises the processing chamber, a first actuator to move the first disk, a second actuator to rotate the pedestal, and a controller to control the first and second actuators.

In another feature, a system comprises the processing chamber, where the first disk includes an adjustable aperture; a first actuator to move the first disk and to adjust the adjustable aperture; a second actuator to rotate the pedestal; and a controller to control the first and second actuators.

In another feature, a system comprises the processing chamber; first and second actuators to move the first disk and the second disk, respectively; a third actuator to at least one of rotate and tilt the pedestal; and a controller to control the first, second, and third actuators.

In another feature, a system comprises the processing chamber, where at least one of the first disk and the second disk includes an adjustable aperture; first and second actuators to move the first disk and the second disk, respectively, and to adjust the adjustable aperture; a third actuator to at least one of rotate and tilt the pedestal; and a controller to control the first, second, and third actuators.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows an example of a substrate processing system comprising a processing chamber that generates an inductively coupled plasma (ICP) to process substrates;

FIG. 1B shows an example of a substrate processing system comprising a processing chamber that generates a capacitively coupled plasma (CCP) to process substrates;

FIGS. 2A and 2B show a grid assembly used in the processing chambers of FIGS. 1A and 1B to accelerate ions from the plasma during substrate processing;

FIG. 3 shows an example of a disk that can be moved between the plasma and a substrate in the processing chamber of FIG. 1A or 1B to vary an etch profile of the substrate;

FIG. 4 shows an example of a disk with an aperture that can be moved between the plasma and a substrate in the processing chamber of FIG. 1A or 1B to vary an etch profile of the substrate;

FIGS. 5A and 5B show an example of a disk that can be moved radially between the plasma and the substrate in the processing chamber of FIG. 1A or 1B to modulate etch rate of the substrate;

FIGS. 6A and 6B shows another example of a disk that can be moved radially between the plasma and the substrate in the processing chamber of FIG. 1A or 1B to modulate etch rate of the substrate;

FIG. 7 shows an example of a disk including an aperture that can be moved between the plasma and a substrate in the processing chamber of FIG. 1A or 1B to etch different regions of the same substrate under different process conditions;

FIG. 8 shows an example of a system including two disks that can be moved between the plasma and a patterned substrate in the processing chamber of FIG. 1A or 1B to etch features of the substrate;

FIG. 9 shows an example of disk with an aperture and a mechanism for adjusting the aperture that can be used in the processing chamber of FIG. 1A or 1B as shown in FIGS. 3-8;

FIG. 10 shows another example of a disk with an adjustable aperture that can be used in the processing chamber of FIG. 1A or 1B as shown in FIGS. 3-8; and

FIGS. 11A-11D show an example of a system for moving a disk between the plasma and a substrate in the processing chamber of FIG. 1A or 1B and for adjusting a size of an aperture on the disk to perform the various operations shown in FIGS. 3-8.

In the drawings, reference numbers may be reused to identify similar and/or identical elements.

### DETAILED DESCRIPTION

Various methods are used to control etching processes in substrate processing systems. For example, a processing chamber in which an etch process is performed on a substrate, may comprise a first chamber where plasma is generated and a second chamber where the substrate is arranged on a pedestal. A grid (e.g., a disc or a plate with holes) may be arranged between the first and second chambers to accelerate ions from the plasma to the substrate. To achieve etch uniformity on the substrate, controls are typically applied from the plasma side. For example, an electromagnetic (EM) field may be applied to the plasma using one or more electromagnets. However, when the EM field is applied or varied, not only the ion distribution changes but several other plasma parameters also change at the same time. The same plasma condition cannot be maintained at two different EM field settings. Further, if an electromagnet located at the center of the processing chamber is used to tune etch uniformity, the plasma density can be altered only at the center region and not at the edges of the substrate. Furthermore, the EM field changes the ions' divergence, plasma potential, and grid focus. Alternatively, etching can be controlled by adjusting grid voltage, changing ion scattering by controlling flow/pressure in the processing chamber, etc. However, these techniques create difficulties for recipe tuning and chamber matching because more than one plasma parameters are changed at the same time.

Unlike the above methods which control etching from the plasma side, the present disclosure provides a system that controls etching without disturbing the plasma. The present disclosure provides an independent tuning knob for center-to-edge etch profile tuning. The system can tune the etch profile to any desired shape without affecting plasma properties. The tuning knob can tune the ion flux to the substrate without changing any plasma parameter. As explained below in detail, by introducing a disk between the plasma and the substrate (specifically, between the grid and the substrate) to block some of the ions from reaching the substrate, the etch profile can be tuned to any desired shape. The disk can be moved across (i.e., laterally or parallel to) the substrate, and/or the substrate can be rotated. An aperture can be added to the disk to allow etching to occur only at a specific location on the substrate. For perfecting a recipe, instead of using separate substrates, many different process conditions can be run on the same substrate by aligning the aperture on different locations on the substrate. A plurality of disks with and without apertures can be used in combination. These and other features of the present disclosure are described below in detail.

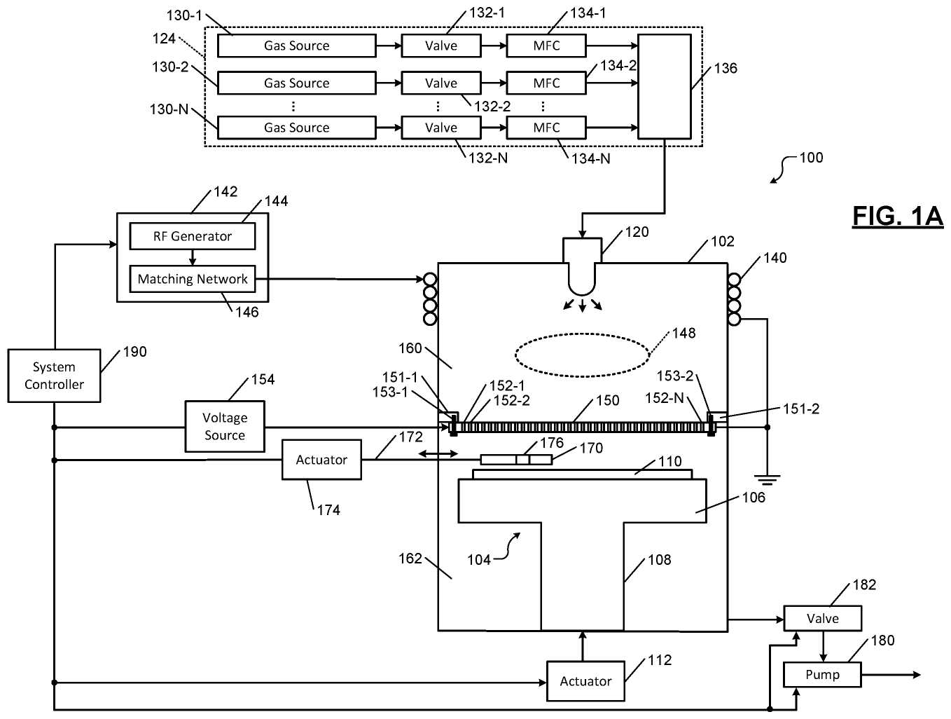

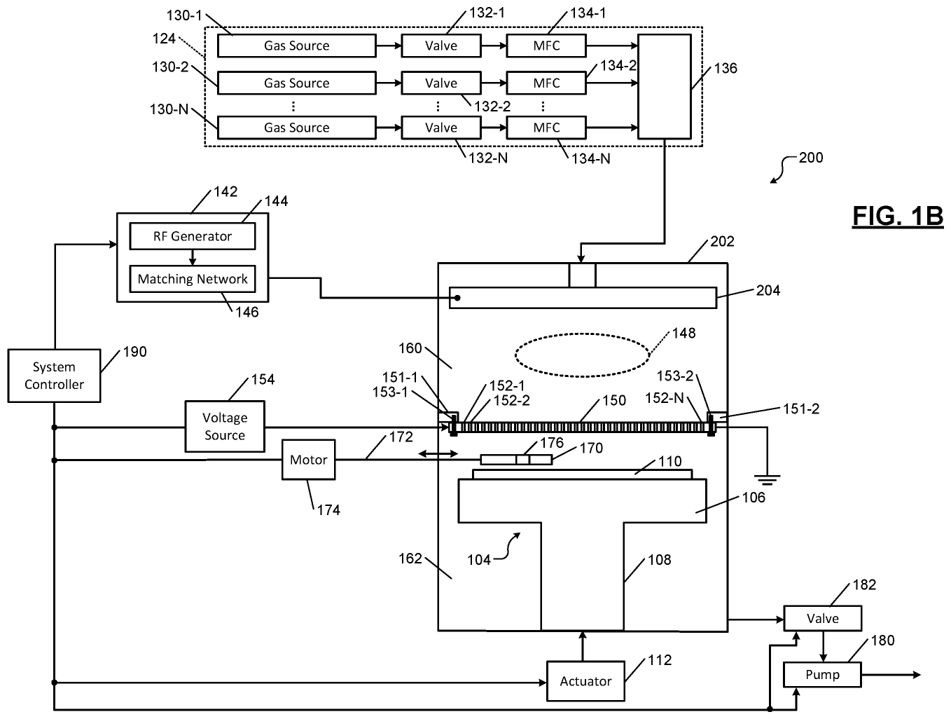

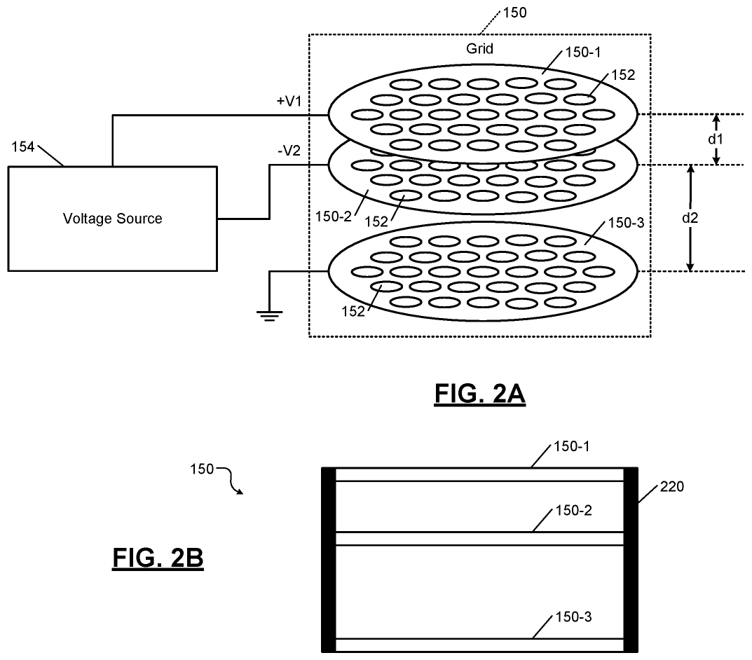

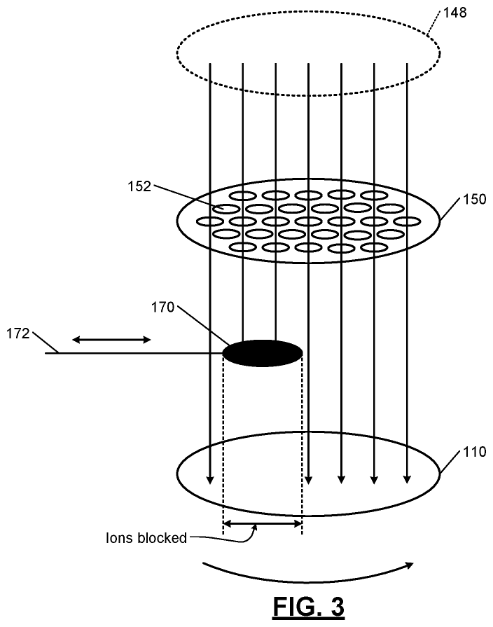

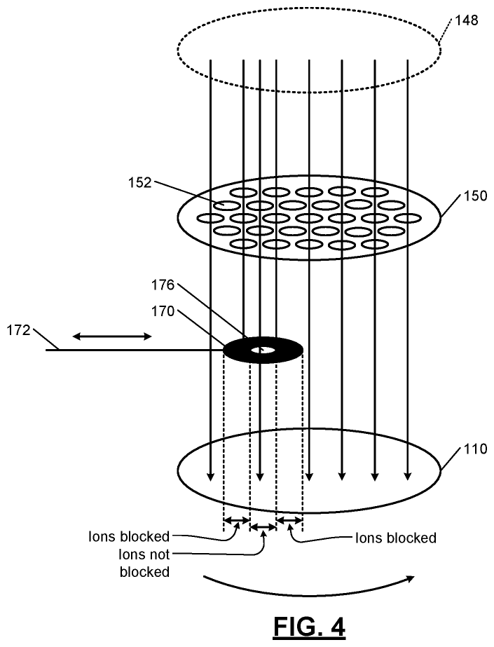

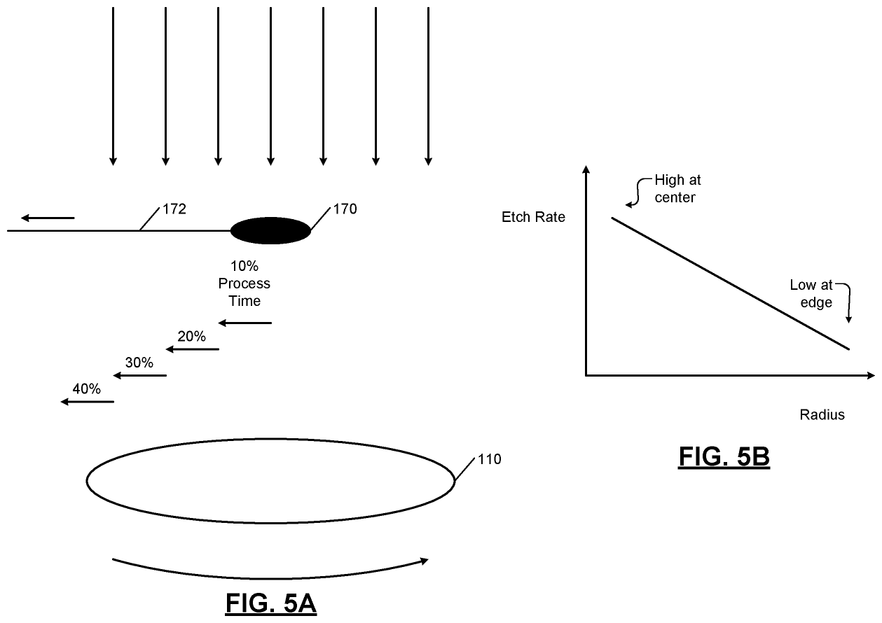

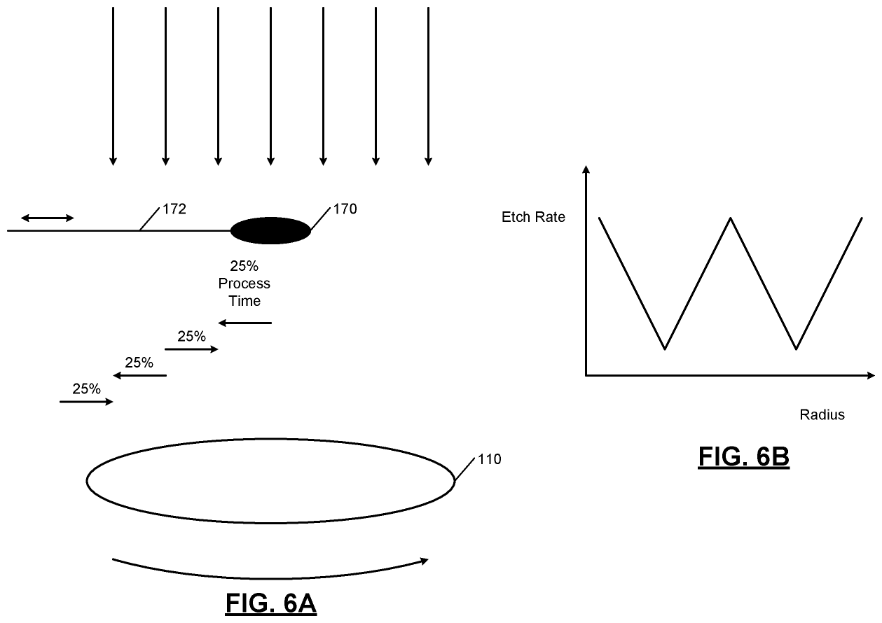

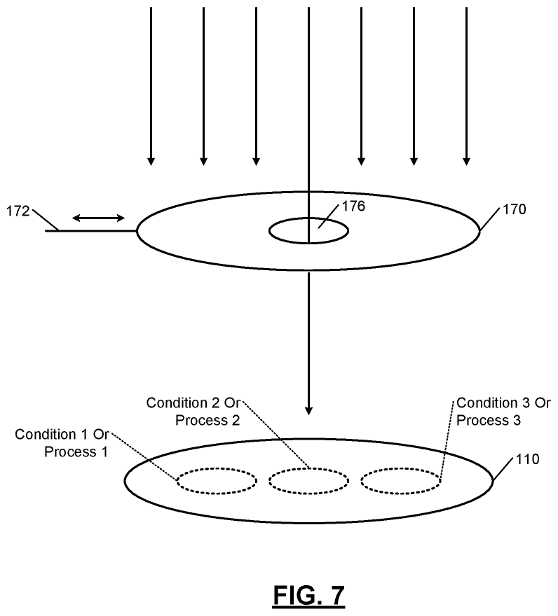

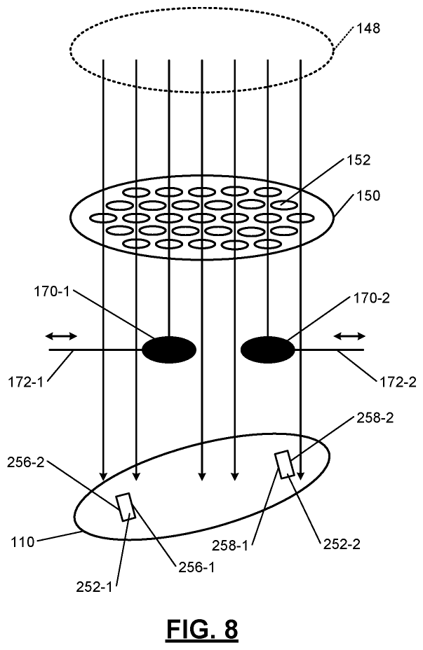

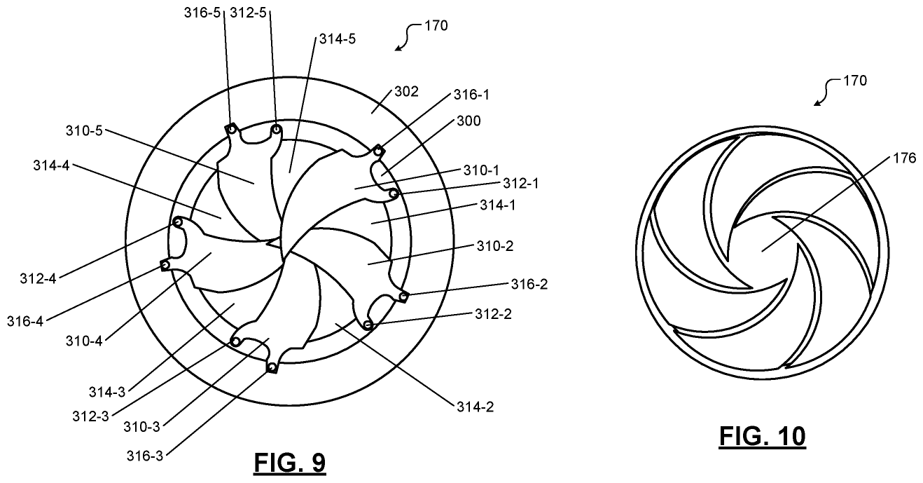

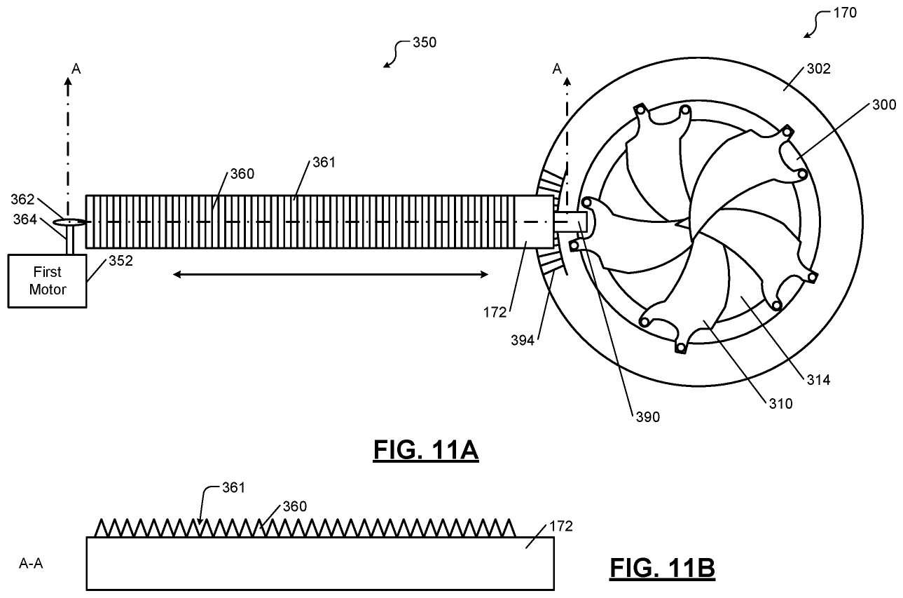

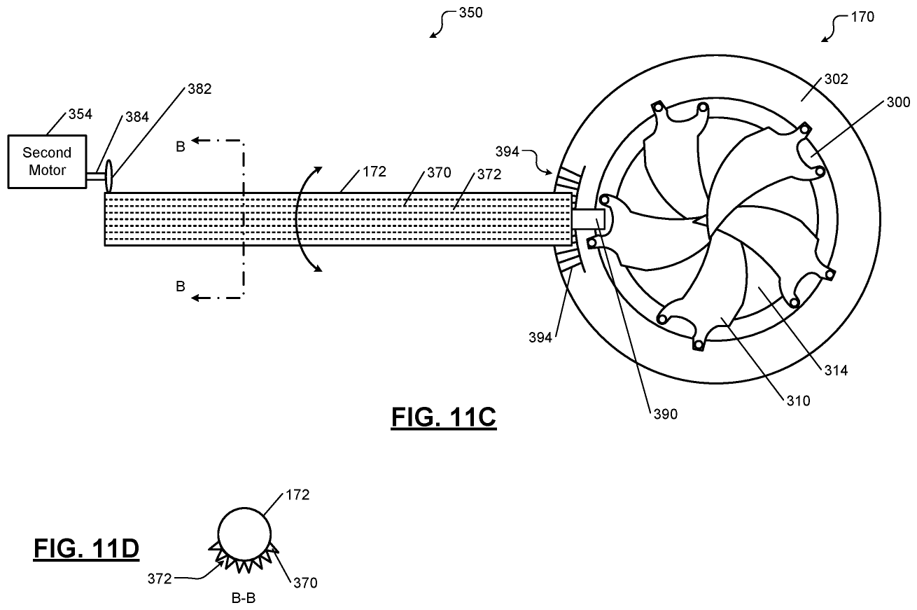

The present disclosure is organized as follows. Initially, examples of substrate processing systems in which one or more disks can be used are shown and described with reference to FIGS. 1A and 1B. An example of a grid used in the processing chambers of FIGS. 1A and 1B is shown and described with reference to FIGS. 2A and 2B. Examples of disks with and without aperture are shown and described with reference to FIGS. 3 and 4. Examples of modulating etch rates using the disks are shown and described with reference to FIGS. 5A-6B. An example of a disk with one or more apertures that can be used to etch portions of the same substrate under different process conditions is shown and described with reference to FIG. 7. An example of a system including a plurality of disks used to etch features of a patterned substrate is shown and described with reference to FIG. 8. Examples of disks with variable apertures are shown and described with reference to FIGS. 9 and 10. An example of a system for moving a disk linearly and for adjusting a size of the aperture on the disk is shown and described with reference to FIGS. 11A-11D.

FIG. 1A shows a substrate processing system 100 according to the present disclosure. The substrate processing system 100 comprises a processing chamber 102. The processing chamber 102 generates inductively coupled plasma (ICP) as described below. The processing chamber 102 comprises a pedestal 104. The pedestal 104 includes a base portion 106 and a stem portion 108. The stem portion 108 extends vertically downwards from a center region of the base portion 106. A substrate 110 is arranged on the base portion 106 during processing. A suitable clamping system (e.g., vacuum clamping, not shown) is used to clamp the substrate 110 to the base portion 106 of the pedestal 104 during processing.

An actuator 112 is coupled to the stem portion 108 of the pedestal 104. The actuator 112 has two or more degrees of freedom. The actuator 112 can move the pedestal 104 vertically along an axis perpendicular to the plane of the substrate 110. The actuator 112 can also rotate the pedestal 104 around the axis. Further, the actuator 112 can tilt the pedestal 104 relative to the axis.

The processing chamber 102 comprises a gas injector 120 that injects one or more gases into the processing chamber 102. The gas injector 120 receives the one or more gases from a gas delivery system 124. The gas delivery system 124 includes one or more gas sources 130-1, 130-2, . . . , and 130-N (collectively the gas sources 130), where N is a positive integer. The gas sources 130 are connected by valves 132-1, 132-2, . . . , and 132-N (collectively the valves 132) and mass flow controllers 134-1, 134-2, . . . , and 134-N (collectively the mass flow controllers 134) to a manifold 136. The manifold 136 is connected to the gas injector 120.

A coil 140 is disposed around an upper portion of the processing chamber 102. An RF generating system 142 supplies RF power to the coil 140. The RF generating system 142 comprises an RF generator 144 and a matching network 146. The RF generator 144 generates the RF power. The matching network 146 matches the impedance of the RF generator 144 with the impedance of the coil 140. The matching network 146 outputs the RF power to the coil 140. A first end of the coil 140 is connected to the RF generating system 142 (i.e., to the matching network 146). A second end of the coil 140 is grounded. The RF power from the coil 140 ignites the one or more gases injected by the gas injector 120 into an upper region of the processing chamber 102 to generate plasma 148.

A grid 150 is arranged in the processing chamber 102 between the gas injector 120 and the pedestal 104. The grid 150 essentially divides (i.e., partitions) the processing chamber 102 into an upper chamber 160 and a lower chamber 162. In general, the upper and lower chambers 160, 162 may also be respectively called the first and second chambers 160, 162. The plasma 148 is generated in the upper chamber 160 as described above. The pedestal 104 and the substrate 110 are located in the lower chamber 162. The grid 150 separates the pedestal 104 and the substrate 110 from the plasma 148 in the upper chamber 160. The plasma 148 is not generated in the lower chamber 162.

For example, the grid 150 may include a single plate with holes 152-1, 152-2, . . . , and 152-N (collectively the holes 152), where N is an integer greater than 1. Alternatively, as shown and described with reference to FIGS. 2A and 2B, the grid 150 may include a plurality of parallel plates with holes that are aligned with each other. The grid 150 is mounted to sidewalls of the processing chamber 102 using a plurality of mounting brackets 151-1 and 151-2 (collectively the mounting brackets 151) and corresponding fasteners 153-1, 153-2 (collectively the fasteners 153). The mounting brackets 151 are electrically insulating. The mounting brackets 151 electrically insulate the grid 150 from the sidewalls of the processing chamber 102.

The grid 150 is biased by a voltage source 154 to control a flow of ions from the plasma 148 to the substrate 110. The biasing of the grid 150 is shown and described in further detail with reference to FIGS. 2A and 2B. Briefly, the voltage source 154 supplies one or more voltages to a first end of the grid 150. A second end of the grid 150 is grounded. By controlling the voltage supplied by the voltage source 154 to the grid 150, the ions from the plasma 148 can be accelerated to a selected energy level. The ions accelerated to the selected energy level pass through the holes 152 of the grid 150 to the substrate 110 in the lower chamber 162.

A disk 170 attached to a rod 172 can be moved laterally between the grid 150 and the substrate 110 using an actuator 174. An example of the actuator 174 is shown and described in deal with reference to FIGS. 11A-11D. The disk 170 can alter the flow of ions from the plasma 148 to the substrate 110 in many ways. For example, the disk 170 may be solid (i.e., without an aperture). In some examples, the disk 170 may include an aperture 176. Various examples of the disk 170 with and without the aperture 176 are shown and described in further detail with reference to FIGS. 3-11D.

Briefly, the disk 170 can selectively prevent some of the ions that have passed through the grid 150 into the lower chamber 162 from reaching the substrate 110, thereby changing an etch profile of the substrate 110. In some examples, the aperture 176 may allow some of the ions that have passed through the grid 150 to continue to flow to a selected region of the substrate 110. Hence, an etch profile of the substrate 110 can be controlled by selectively managing ions that are allowed to reach the substrate 110.

The disk 170 may be made of a low sputter material. Non-limiting examples of such material include diamond-like carbon (DLC) and heavy metals such as tantalum (Ta) and molybdenum (Mo) (i.e., metals with relatively large atomic numbers that do not generate secondary emissions when bombarded with ions from the plasma 148). In general, the disk 170 may be made of material including but not limited to DLC, Ta, Mo, aluminum (Al), alumina (Al₂O₃), chromium (Cr), Beryllium (Be), tantalum carbide (TaC), and lead zirconate titanate (PZT) ceramic.

As shown and described in detail with reference to FIGS. 3-11D, in some examples, the disk 170 may be relatively small in size (e.g., diameter) compared to the substrate 110. In other examples, the disk 170 may be relatively large in size (e.g., of diameter slightly less than the substrate 110) compared to the substrate 110. In some examples, the disk 170 may include more than one aperture. In other examples, more than one disk (with or without apertures) controlled by respective actuators may be arranged between the grid 150 and the substrate 110. An example of the actuator is shown and described in deal with reference to FIGS. 11A-11D. In some examples, the disk 170 is moved, and the substrate 110 may be rotated. In other examples, the disk 170 is moved, and the substrate 110 may be stationary and/or tilted. These features are explained in further detail with reference to FIGS. 3-11D.

A pump 180 is coupled to the processing chamber 102 via a valve 182. The pump 180 and the valve 182 may control pressure in the processing chamber 102 and evacuate reactants from the processing chamber 102 during processing. A system controller 190 may control the components of the substrate processing system 100 described above.

FIG. 1B shows a substrate processing system 200 according to the present disclosure. The substrate processing system 200 comprises a processing chamber 202. The processing chamber 202 generates capacitively coupled plasma (CCP) as described below. Some of the components of the substrate processing system 200 are similar to the components of the substrate processing system 100 shown and described above with reference to FIG. 1A. These similar components of the substrate processing system 200 are denoted by the same reference numerals as those used in the substrate processing system 100. These components are not described again for brevity.

The processing chamber 202 comprises a gas distribution device 204 such as a showerhead (hereinafter the showerhead 204) that introduces and distributes process gases into the processing chamber 202. The showerhead 204 may include a stem portion including one end connected to a top plate of the processing chamber 202. A base portion of the showerhead 204 is generally cylindrical and extends radially outwardly from an opposite end of the stem portion at a location that is spaced from the top plate of the processing chamber 202. A substrate-facing surface or faceplate of the base portion of the showerhead 204 includes a plurality of holes (not shown) through which process gases flow. The manifold 136 of the gas distribution system 124 is connected to the showerhead 204.

To generate plasma, the showerhead 204 and the pedestal 104 are respectively used as upper and lower electrodes. For example, the RF power from the RF generating system 142 is applied to the showerhead 204, and the pedestal 104 is grounded. For example, the pedestal 104 may be DC grounded, AC grounded, or floating. Alternatively, the RF power from the RF generating system 142 is applied to the pedestal 104, and the showerhead 204 is grounded. For example, the showerhead 204 may be DC grounded, AC grounded, or floating.

The grid 150 is arranged in the processing chamber 202 between the showerhead 204 and the pedestal 104. The grid 150 essentially divides the processing chamber 202 into the upper chamber 160 and the lower chamber 162. The plasma 148 is generated in the upper chamber 160 by applying RF power to the showerhead 204 or the pedestal 104 as described above. The remaining components of the substrate processing system 200 are described with reference to FIG. 1A, and their description is therefore not repeated for brevity.

FIGS. 2A and 2B show an example of the grid 150 used in the processing chambers 102, 202 shown in FIGS. 1A and 1B. FIG. 2A schematically shows an arrangement of a plurality of plates of the grid 150 and the power supplied to the plates of the grid 150 by the voltage source 154. FIG. 2B shows a side cross-sectional view of the plates of the grid 150 mounted in a frame 220 to form the grid 150 (also called the grid assembly 150 or the grid system 150).

In FIG. 2A, for example, the grid 150 includes three plates 150-1, 150-2, and 150-3 that are arranged parallel to each other. For simplicity of illustration, the frame 200 is omitted in FIG. 2A and is shown instead in FIG. 2B. The plate 150-1 faces the plasma 148. The plate 150-3 faces the substrate 110. For example, a distance d1 between the plates 150-1 and 150-2 is less than a distance d2 between the plates 150-2 and 150-3. For example, a ratio of d1:d2 may be about 1:2. The holes 152 in the plates 150-1, 150-2, and 150-3 are aligned with each other.

FIG. 2B shows a cross-sectional view of the grid 150 mounted in the frame 220. For example, the plates 150-1, 150-2, and 150-3 are mounted in the frame 220 made of an electrically insulating material to form the grid assembly (or the grid system) 150. The frame 220 including the plates 150-1, 150-2, and 150-3 is mounted to the sidewalls of the processing chambers 102, 202 using the mounting brackets 151 and the fasteners 153 as shown in FIGS. 1A and 1B.

In FIG. 2A, for example, the voltage source 154 applies a positive DC voltage +V1 to the plate 150-1 to accelerate ions from the plasma 148. For example, a maximum value of +V1 may be about +2000V. The voltage source 154 applies a negative DC voltage −V2 to the plate 150-2 to focus the ions. For example, a maximum value of −V2 may be about −1000V. The plate 150-3 is grounded to prevent the electric field created around the plates 150-1 and 150-2 from interfering with the processing of the substrate 110.

In FIGS. 3-11D, various configurations and arrangements of the disk 170 are shown and described. These configurations and arrangements of the disk 170 can be employed in the processing chambers 102, 202 shown in FIGS. 1A and 1B. Throughout the present disclosure, the disk 170 and the aperture 176 are shown and described as being circular in shape. However, the disk 170 and the aperture 176 can have other shapes. For example, disk 170 and the aperture 176 can be polygonal.

FIG. 3 shows an example of the disk 170. For example, the disk 170 is relatively small in size compared to the substrate 110. For example, a diameter of the disk 170 is less than half the diameter of the substrate 110. The disk 170 can be moved parallel to the grid 150 and the substrate 110 between the grid 150 and the substrate 110. The substrate 110 can also be rotated by rotating the pedestal 104 while the disk 170 is moved. By moving the disk 170 radially across the substrate 110, by controlling the speed of the disk 170, and/or by controlling the rotation of the substrate 110, the entire surface of the substrate 110 can be selectively covered and, hence, the etching of the substrate 110 can be controlled in a more selective manner.

For example, since the disk 170 selectively blocks some of the ions that have passed through the grid 150 from the substrate 110, the ions can be prevented from reaching particular regions of the substrate 110 at particular times during the etching process by moving the disk 170 and/or rotating the substrate 110. Blocking the ions using the disk 170 reduces the etch rate at the region on the substrate 110 that is covered (eclipsed) by the disk 170 and is consequently not bombarded by the ions due to the blockage of the ions by the disk 170. Different etch profiles can be achieved on the substrate 110 using the disk 170 as described below in detail with reference to FIGS. 5-8.

Typically, the etching process is controlled by varying gas flow, acceleration voltage of the grid 150, and so on, which can disturb the plasma 148. In contrast, controlling the etching process using the disk 170 does not disturb the plasma 148 since none of the plasma related parameters are varied to control the etching process.

FIG. 4 shows an example of the disk 170 including the aperture 176. The description of FIG. 4 is similar to the description of FIG. 3 except that the disk 170 is not entirely solid or impervious to the ions. Instead, only the solid portion of the disk 170 blocks the ions while the aperture 176 in the disk 170 allows the ions to pass through to the substrate 110. The aperture 176 provides additional control over the etching process and allows creation of additional etch profiles on the substrate 110. Blocking the ions using the solid portion of the disk 170 reduces the etch rate at a corresponding region on the substrate 110 that is covered (eclipsed) by the solid portion of the disk 170. Conversely, passing the ions through the aperture 176 increases the etch rate at a corresponding region on the substrate 110.

The aperture 176 is shown at the center of the disk 170 for example only. Instead, the aperture 176 can be located elsewhere on the disk 170. Further, the size of the aperture 176 (i.e., the opening of the aperture 176 or the amount by which the aperture 176 opens) can be controlled (varied) as described below in detail with reference to FIGS. 11A-11D. Further, while not shown, the disk 170 can include a plurality of apertures 176. The plurality of apertures 176 can have different geometries (e.g., shapes and sizes). The plurality of apertures 176 can be arranged in any manner on the disk 170 depending on requirements of the etching process performed on the substrate 110. Furthermore, in some examples, the disk 170 can include one adjustable aperture and at least one aperture having a fixed size.

FIGS. 5A-6B show examples of etch rate modulation of the substrate 110 that can be achieved by moving the disk 170 between the grid 150 and the substrate 110 in different ways. FIG. 5A shows an example of etch rate modulation of the substrate 110 that can be achieved by moving the disk 170 between the grid 150 and the substrate 110. For example, during an etching process performed on the substrate 110 in a processing chamber (e.g., element 102 or 202 shown in FIGS. 1A and 1B), the disk 170 can be gradually moved radially outward from above the center of the substrate 110 in steps as follows.

For example only, during the etching process, the disk 170 is initially held at a first location above the center of the substrate 110 for about 10% of the total process time. Alternatively, any other percentage of the total process time may be used. Then, while the etching process continues, the disk 170 is moved radially outward from above the center of the substrate 110 to a second location by a first predetermined distance. For example only, the first predetermined distance may be about one-fourth of the radius of the substrate 110. Alternatively, the first predetermined distance may be any other fraction of the radius of the substrate 110. For example only, the disk 170 is held at the second location for about 20% (or any other percentage) of the total process time.

Then, while the etching process continues, the disk 170 is moved radially outward from the second location to a third location by a second predetermined distance. For example only, the second predetermined distance may be about one-fourth (or any other fraction) of the radius of the substrate 110. For example only, the disk 170 is held at the third location for about 30% (or any other percentage) of the total process time.

Then, while the etching process continues, the disk 170 is moved radially outward from the third location to a fourth location by a third predetermined distance. For example only, the third predetermined distance may be about one-fourth (or any other fraction) of the radius of the substrate 110. For example only, the disk 170 is held at the fourth location for about 40% (or any other percentage) of the total process time.

In addition, throughout the etching process the substrate 110 may be rotated while moving the disk 170 as described above. The movement of the disk 170 described above creates a linear center-to-edge etch rate modulation shown in FIG. 5B. Alternatively, depending on the process, the disk 170 may be moved in any other manner (including direction, moving speed, number of steps, distance per step, duration per step, etc.) to achieve any other etch rate modulation.

Further, while not shown in FIG. 5A, the disk 170 may include the aperture 176. In some examples, the size of the aperture 176 may be varied (e.g., as shown and described below in detail with reference to FIGS. 9-11D). In other examples, more than one disk 170 with or without one or more apertures 176 (of variable or fixed sizes) can be moved in different ways (e.g., as shown and described below in detail with reference to FIG. 8) to achieve complex etch profiles on the substrate 110.

FIG. 6A shows another example of etch rate modulation of the substrate 110 that can be achieved by moving the disk 170 between the grid 150 and the substrate 110. For example, during an etching process performed on the substrate 110 in a processing chamber (e.g., element 102 or 202 shown in FIGS. 1A and 1B), the disk 170 can be gradually moved radially outward and inward (i.e., back and forth) from above the center of the substrate 110 in steps as follows.

For example only, during the etching process, the disk 170 is initially held at a first location above the center of the substrate 110 for about 25% (or any other percentage) of the total process time. Then, while the etching process continues, the disk 170 is moved radially outward from the center of the substrate 110 to a second location by a first predetermined distance. For example only, the first predetermined distance may be a fraction of the radius of the substrate 110. For example, the disk 170 is held at the second location for a predetermined percentage of the total process time.

Then, while the etching process continues, the disk 170 is moved radially inward (i.e., towards the center of the substrate 110) from the second location to a third location by a second predetermined distance. For example, the second predetermined distance may be a fraction of the radius of the substrate 110. For example, the disk 170 is held at the third location for a predetermined percentage of the total process time.

Then, while the etching process continues, the disk 170 is moved radially outward from the third location to a fourth location by a third predetermined distance. For example, the third predetermined distance may be a fraction of the radius of the substrate 110. For example, the disk 170 is held at the fourth location for a predetermined percentage of the total process time.

Then, while the etching process continues, the disk 170 is moved radially inward from the fourth location to a fifth location by a fourth predetermined distance. For example, the fourth predetermined distance may be a fraction of the radius of the substrate 110. For example, the disk 170 is held at the fourth location for a predetermined percentage of the total process time.

In some examples, the predetermined distances for each movement step of the disk 170 described above may be equal. In other examples, the predetermined distances may be selected to form a desired etch profile on the substrate 110. In some examples, the predetermined percentages of the total process time between each movement step of the disk 170 described above may be equal. In other examples, the predetermined percentages of the total process time may be selected to form a desired etch profile on the substrate 110.

In addition, throughout the etching process, the substrate 110 may be rotated while moving the disk 170 as described above. The movement of the disk 170 described above creates a W-shaped rate modulation shown in FIG. 6B. Alternatively, depending on the process, the disk 170 may be moved in any other manner (e.g., using any other sequence and durations of movements, and/or by varying the direction, moving speed, number of steps, distance per step, duration per step, etc.) to achieve any other etch rate modulation.

Further, while not shown in FIG. 6A, the disk 170 may include the aperture 176. In some examples, the size of the aperture 176 may be varied (e.g., as shown and described below in detail with reference to FIGS. 9-11D). In other examples, more than one disk 170 with or without one or more apertures 176 (of variable or fixed sizes) can be moved in different ways (e.g., as shown and described below in detail with reference to FIG. 8) to achieve complex etch profiles on the substrate 110.

FIG. 7 shows another example of the disk 170 including the aperture 176. For example, the disk 170 is relatively larger in size than the disks 170 shown in FIGS. 5A-6B. For example, a diameter of the disk 170 may be slightly less than the diameter of the substrate 110. For example, the diameter of the disk 170 may be more than half the diameter of the substrate 110 but less than the diameter of the substrate 110. The disk 170 can be moved parallel to the grid 150 and substrate 110 between the grid 150 and the substrate 110.

The disk 170 can be moved to different locations. At each location, a different etching process can be performed on the substrate 110. Alternatively, at each location, the same etching process can be performed under different conditions (e.g., different process time, different acceleration voltage of the grid 150, etc.). Accordingly, different regions of the substrate 110 can be etched using different etching processes or process conditions. This feature is helpful in trying out different recipes or fine tuning recipes on the same substrate 110. This feature can also be used to create complex etch profiles on the substrate 110.

For example, with the disk 170 at a first location, a first region on the substrate 110 is etched using a first process or a first process condition. Then the disk 170 is moved to a second location, and the substrate 110 is etched using a second process or a second process condition for the same process. Then the disk 170 is moved to a third location, and the substrate 110 is etched using a third process or a third process condition for the same process; and so on. While not shown, in some examples, the disk 170 may include a plurality of apertures 176, and the size of one or more apertures 176 may be variable (as shown and described below with reference to FIGS. 9-11D). In some examples, the substrate 110 may also be rotated.

FIG. 8 shows an example of a system that uses two disks 170-1, 170-2 between the grid 150 and the substrate 110 during an etching process. The two disks 170-1, 170-2 are attached to respective rods 172-1, 172-2. The two disks 170-1, 170-2 can be moved similar to the disk 170 as described above using respective actuators. An example of actuators for moving one disk is shown and described below with reference to FIGS. 11A-11D.

For example, the two disks 170-1, 170-2 can be moved in the same or opposite directions between the grid 150 and the substrate 110. For example only, the two disks 170-1, 170-2 are shown as being arranged in the same plane. Instead, the two disks 170-1, 170-2 may be arranged in different planes parallel to the grid 150. Further, while not shown in FIG. 8, at least one of the two disks 170-1, 170-2 can include one or more apertures 176 as described above. At least one of the two disks 170-1, 170-2 can include an adjustable aperture. At least one of the two disks 170-1, 170-2 can include one adjustable aperture and at least one aperture having a fixed size. Furthermore, the two disks 170-1, 170-2 and their respective apertures can have the same geometry (e.g., size and shape) or different geometries.

For example only, the substrate 110 may be patterned and may include a plurality features such as pillars 250-1, 250-2. For example only, the substrate 110 is shown in a tilted position. However, the teachings of FIG. 8 apply equally to substrates including other features and to substrates that are not tilted during etching processes (i.e., that are held parallel to the two disks 170-1, 170-2).

For example, since the substrate 110 is tilted relative to the two disks 170-1, 170-2, the pillar 252-2 is closer to the grid 150 than the pillar 252-1. Consequently, the pillar 252-2 receives more ions than the pillar 252-1. Accordingly, the ion density for the pillar 252-2 is higher than the ion density for the pillar 252-1.

Each of the pillars 250-1, 250-2 has two sides: a first side facing the center of the substrate 110 and a second side facing the outer diameter (OD) of the substrate 110. The first sides of the pillars 250-1, 250-2 facing the center of the substrate 110 are respectively denoted as 256-1, 258-1. The second sides of the pillars 250-1, 250-2 facing the OD of the substrate 110 are respectively denoted as 256-2, 258-2.

Due to the tilted substrate 110, the second side 258-2 of the pillar 252-2 facing the OD of the substrate 110 receives more ions than the first side 256-1 of the pillar 252-2 facing the center of the substrate 110. Consequently, the second side 258-2 of the pillar 252-2 facing the OD of the substrate 110 is etched more (i.e., at a higher etch rate) than the first side 256-1 of the pillar 252-2 facing the center of the substrate 110.

In general, by using one or more disks 170 with or without one or more apertures 176, moving the disks 170, adjusting the apertures 176, and holding the substrate 110 in a stationary, rotating, or tilted position, various etch profiles on the substrate 110 can be achieved. Examples of adjustable apertures and a system to move the disk 170 and vary the size of the aperture 176 are now described in detail with reference to FIGS. 9-11D.

FIGS. 9 and 10 show examples of disks with adjustable apertures. FIG. 9 shows an example of a disk with a mechanism used for adjusting a size of an aperture of the disk in detail. The mechanism used to adjust the size of the aperture can be similar to the mechanism used to adjust apertures in cameras. FIG. 10 shows a schematic of another example of a disk including an adjustable aperture without showing an associated mechanism to adjust the size of the aperture.

In FIG. 9, an example of the disk 170 with the aperture is shown. For example, the disk 170 comprises an inner ring 300, an outer ring 302, and a plurality of adjustable blades that are mounted to the inner and outer rings 300, 302 as described below. The inner ring 300 is stationary. The outer ring 302 is rotatable relative to the inner ring 300.

For example, a first plurality of blades 310-1, 310-2, . . . , and 310-5 (collectively the first blades 310) is connected to the inner ring 300 by respective first pivot assemblies 312-1, 312-2, . . . , and 312-5. The first blades 310 are also connected to the outer ring 302 by respective second pivot assemblies 316-1, 316-2, . . . , and 316-5. A second plurality of blades 314-1, 314-2, . . . , and 314-5 (collectively the second blades 314) is connected to the outer ring 302 by respective pivot assemblies (not shown).

As the outer ring 302 is rotated relative to the stationary inner ring 300 (e.g., using a system shown in FIGS. 11A-11D), the first and second blades 310, 314 move radially inward or outward, which changes the size of the aperture formed by the first and second blades 310, 314. The shape of the aperture is closer to a circular shape as the number of blades is increased. FIG. 10 shows another example of the disk 170 with an adjustable aperture 176. Many other types and arrangements of blades may be used to provide the adjustable aperture 176 in the disk 170.

FIGS. 11A-11D show an example of a system 350 that can move the disk 170 and adjust the size of the aperture 176 in the disk 170. For example, the system 350 can move the disk along a first axis parallel to the rod 172, which is also parallel to the grid 150 and the substrate 110 as follows. The system 350 can also increase or decrease the size of the aperture 176 along a second axis perpendicular to the first axis as follows.

The system 350 comprises two motors: a first motor 352 shown in FIG. 11A and a second motor 354 shown in FIG. 11C. For example, the first and second motors 352, 354 can be stepper motors. The first motor 352 moves the rod 172 and the disk 170 linearly along the first axis as described below in detail. The second motor 354 rotates the rod 172 around the first axis and adjusts the size of the aperture 176 as described below in detail.

When the disk 170 does not include the aperture 176, the second motor 354 can be omitted. When more than one disk 170 is used, the movement of each disk 170 is controlled by a respective first motor 352, and the size of the aperture 176 of each disk 170 (if the aperture 176 is included in the disk 170) is controlled by a respective second motor 354.

In FIG. 11A, for example, the rod 172 is cylindrical. The rod 172 includes two sets of teeth. A first set of teeth 360 is arranged on a first half of a surface area of the rod 172. The first half of the surface area of the rod 172 includes an upper half of the rod 172 facing the grid 150. The teeth 360 are arranged along the length of the rod 172. The teeth 360 are arcuate. The teeth 360 and grooves 361 between the teeth 360 extend circumferentially on the upper half of the rod 172.

FIG. 11B shows a longitudinal cross-sectional view of the rod 172 taken along a line A-A shown in FIG. 11A. FIG. 11B shows the arrangement of the teeth 360 and the grooves 361 on the rod 172. The first motor 352 includes a gear 362 mounted on a shaft 364 of the first motor 352. At a first end of the rod 172, the gear 362 engages with the teeth 360 on the rod 172 and moves the rod 172 along the first axis parallel to the length of the rod 172.

In FIG. 11C, the rod 172 includes a second set of teeth 370. The teeth 370 are arranged on a second half of the surface area of the rod 172 of the rod 172. The second half of the surface area of the rod 172 includes a lower half of the rod 172 facing the substrate 110. The teeth 370 and grooves 372 between the teeth 370 extend longitudinally on the lower half of the rod 172.

FIG. 11D shows a transverse cross-sectional view of the rod 172 taken along a line B-B shown in FIG. 11C. FIG. 11D shows the arrangement of the teeth 370 and the grooves 372 on the rod 172. The second motor 354 includes a gear 382 mounted on a shaft 384 of the second motor 354. At the first end of the rod 172, the gear 382 engages with the teeth 370 and rotates the rod 172 around the first axis.

A second end of the rod 172 includes a bracket 390 that extends along the length of the rod 172. The bracket 390 is attached to the stationary inner ring 300 of the disk 170. The rotatable outer ring 302 of the disk 170 includes a third set of teeth 394 on a portion of an upper surface of the outer ring 302. The teeth 370 of the rod 172 engage with the teeth 394 on the upper surface of the outer ring 302. When the second motor 354 rotates the gear 382, the rod 172 rotates around the first axis. The turning of the rod 172 rotates the outer ring 302. The rotation of the outer ring 302 moves the first and second blades 310, 314, which in turn adjusts the size of the aperture 176.

The gear 362 of the first motor 352 stays engaged with the teeth 360 while the rod 172 is rotated around the first axis. The gear 382 of the second motor 354 stays engaged with the teeth 370 and the teeth 370 stay engaged with the teeth 394 while the first motor 352 moves rod 172 along the first axis. Accordingly, the rod 172 can be moved bi-directionally along the first axis independently of the status of aperture 176 (i.e., without disturbing the size of the aperture 176). The rod 172 can also be rotated around the first axis (i.e., the size of the aperture 176 can be changed) independently of the linear position of the rod 172 along the first axis.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A processing chamber comprising:
a grid including a plurality of holes arranged in the processing chamber, the grid partitioning the processing chamber into a first chamber in which plasma is generated and a second chamber in which a pedestal is configured to support a substrate; and
a first disk arranged in the second chamber, the first disk being movable between the grid and the substrate when supported on the pedestal.

2. The processing chamber of claim 1 wherein the first disk is movable parallel to the grid.

3. The processing chamber of claim 1 wherein the first disk blocks ions from the plasma from reaching the substrate.

4. The processing chamber of claim 1 wherein the first disk includes at least one or more apertures.

5. The processing chamber of claim 1 wherein the first disk includes an adjustable aperture.

6. The processing chamber of claim 1 wherein the first disk includes an adjustable aperture and an aperture of a fixed size.

7. The processing chamber of claim 1 wherein the first disk is made of a material selected from a group consisting of diamond-like carbon (C), tantalum (Ta), molybdenum (Mo), aluminum (Al), alumina (Al₂O₃), chromium (Cr), Beryllium (Be), tantalum carbide (TaC), and lead zirconate titanate (PZT) ceramic.

8. The processing chamber of claim 1 wherein the first disk has a smaller diameter than the substrate.

9. The processing chamber of claim 1 further comprising a second disk arranged in the second chamber, the second disk being movable parallel to the grid between the grid and the substrate.

10. The processing chamber of claim 9 wherein the first disk and the second disk are coplanar.

11. The processing chamber of claim 9 wherein the first disk and the second disk have the same geometry.

12. The processing chamber of claim 9 wherein the first disk and the second disk have different geometries.

13. The processing chamber of claim 9 wherein at least one of the first disk and the second disk includes one or more apertures.

14. The processing chamber of claim 9 wherein at least one of the first disk and the second disk includes an adjustable aperture.

15. The processing chamber of claim 9 wherein:
at least one of the first disk and the second disk includes an adjustable aperture; and
at least one of the first disk and the second disk includes an aperture of a fixed size.

16. A system comprising:
the processing chamber of claim 1;
an actuator to move the first disk; and
a controller to control the actuator.

17. A system comprising:
the processing chamber of claim 1;
a voltage source to supply a voltage to the grid;
an actuator to move the first disk; and
a controller to control the voltage supplied to the grid and to control the actuator.

18. A system comprising:
the processing chamber of claim 1, wherein the first disk includes an adjustable aperture;
an actuator to move the first disk and to adjust the adjustable aperture; and
a controller to control the actuator.

19. A system comprising:
the processing chamber of claim 9;
first and second actuators to move the first disk and the second disk, respectively; and
a controller to control the first and second actuators.

20. A system comprising:
the processing chamber of claim 9, wherein at least one of the first disk and the second disk includes an adjustable aperture;
first and second actuators to move the first disk and the second disk, respectively, and to adjust the adjustable aperture; and
a controller to control the first and second actuators.

21. A system comprising:
the processing chamber of claim 1;
a first actuator to move the first disk;
a second actuator to rotate the pedestal; and
a controller to control the first and second actuators.

22. A system comprising:
the processing chamber of claim 1, wherein the first disk includes an adjustable aperture;
a first actuator to move the first disk and to adjust the adjustable aperture;
a second actuator to rotate the pedestal; and
a controller to control the first and second actuators.

23. A system comprising:
the processing chamber of claim 9;
first and second actuators to move the first disk and the second disk, respectively;
a third actuator to at least one of rotate and tilt the pedestal; and
a controller to control the first, second, and third actuators.

24. A system comprising:
the processing chamber of claim 9, wherein at least one of the first disk and the second disk includes an adjustable aperture;
first and second actuators to move the first disk and the second disk, respectively, and to adjust the adjustable aperture;
a third actuator to at least one of rotate and tilt the pedestal; and
a controller to control the first, second, and third actuators.
